(19) United States
(12) Patent Application Publication
(10) Pub. No.: US 2006/0145301 A1
(43) Pub. Date: Jul. 6, 2006

(54) Semiconductor chip and semiconductor device

(75) Inventors: Hideaki Saito, Tokyo (JP); Yasuhiko Hagihara, Tokyo (JP); Hiroaki Ikeda, Tokyo (JP)

Correspondence Address: Paul J. Esatto, Jr.;Scully, Scott, Murphy and & Presser, 400 Garden City Plaza, Garden City, NY, 11530, US

(73) Assignees: NEC Corporation, Tokyo (JP); Elpida Memory, Inc., Tokyo (JP)

(21) Appl. No.: 11/326,170

(22) Filed: Jan. 5, 2006

(30) Foreign Application Priority Data
Jan. 5, 2005 (JP) 2005-000591

(51) Int. Cl. H01L 29/93

(52) U.S. Cl. 257/598

(57) ABSTRACT

A wire embedded in a semiconductor substrate is covered with an insulating film, and a bias voltage is applied to the semiconductor substrate or to the wire to form a depletion layer extending from an edge of the insulating film. Alternatively, a semiconductor layer having a different conductivity type from the semiconductor substrate is formed within the semiconductor substrate to surround the insulating film.

### BACKGROUND OF THE INVENTION

1. Field of the Invention

The present invention relates to a semiconductor chip and a semiconductor device which have wires embedded in a semiconductor substrate that serve as current paths through which a current flows in response to a transmission signal.

2. Description of the Related Art

Semiconductor integrated circuit devices have been improved in integration density to provide increasingly higher performance and capacity by virtue of the progress of miniaturization technologies. However, since semiconductor elements cannot become more miniaturized, the introduction of novel technologies has been needed in order to further increase integration density. As an example of such technologies, there has been proposed a three-dimensional semiconductor device which has a plurality of semiconductor chips arranged in a stack. Japanese laid-open patent publication No. H04-196263, for example, describes a technology for realizing a large-scale semiconductor integrated circuit device without changing the chip area by stacking a plurality of semiconductor chips. Japanese laid-open patent publication No. H04-196263 discloses an example in which a memory function chip, formed with a memory circuit, is mounted on a main chip which is formed with a semiconductor integrated circuit. Also, Japanese laid-open patent publication No. 2002-26283 describes a multi-layer memory which realizes an increase in capacity by stacking a plurality of semiconductor devices which are formed with memory cell arrays.

FIG. 1 is a side sectional elevation illustrating an exemplary configuration of a three-dimensional semiconductor device.

As illustrated in FIG. 1, in a three-dimensional semiconductor device which has a plurality of semiconductor chips 1 arranged in a stack, inter-chip wires are required for connecting one chip to another, in addition to normal wires routed in chip planes (hereinafter called the “in-plane wires”). Employed as the inter-chip wires are through wires 2 each extending from the top surfaces to the bottom surfaces of substrates of the semiconductor chips. Each through wire 2 is embedded in a throughhole pierced through semiconductor chips 1 through insulating film 3.

For example, Non-Patent Document 1 (K. Takahashi et al., “Current Status of Research and Development for Three-Dimensional Chip Stack Technology, Japanese Journal of Applied Physics, Vol. 40, pp. 3032-3037, April 2001) introduces an example in which an Si semiconductor substrate, which is fabricated into a semiconductor chip, is formed in a thickness of 50 μm, and is formed with a 10-μm square throughhole which extends from the top surface to the bottom surface of the Si semiconductor substrate, and the throughhole is filled with a metal which serves as wiring material to form a through wire for connecting one chip to another. The use of such a through wire can improve the wiring density to provide a configuration which comprises several hundreds of inter-chip wires.

However, the foregoing through wire needs a width of 10 μm or more, unlike the in-plane wire which has a width of 1 μm or less. This is attributable to difficulties in forming a throughhole having a high aspect ratio through a semiconductor substrate with high accuracy due to process-related restrictions. Also, this is because the size of the through wire must be formed larger by an order of magnitude than several μm which is the accuracy between chips in order to align the through wires of stacked semiconductor chips to one another. Since the through wire has a cross-sectional area larger than the in-plane wire for the reasons mentioned above, the through wire largely differs from the in-plane wire in electric characteristics.

FIG. 2 is a schematic diagram illustrating a through wire which is surrounded by the three-dimensional semiconductor device illustrated in FIG. 1.

As described above, through wire 5 is embedded in a throughhole pierced through semiconductor substrate 4 with insulating film 6 sandwiched therebetween. Generally, since wiring resistance is reciprocally proportional to the cross-sectional area of a wire, through wire 5 having a larger cross-sectional area has a smaller resistance value than in-plane wire. However, since a parasitic capacitance between a wire and semiconductor substrate 4 is proportional to the area of the substrate opposing the wire, a parasitic capacitance between through wire 5 and semiconductor substrate 4 is larger than that between the in-plane wire and semiconductor substrate 4 because of a larger cross-sectional area and a longer perimeter length of through wire 5.

For example, when a circular through wire having a diameter of 20 μm in the cross section is formed within semiconductor substrate 4 with an insulating film of 250 nm thick sandwiched therebetween, the parasitic capacitance of 0.45 pF is produced between the through wire and semiconductor substrate 4 if semiconductor substrate 4 has a thickness of 50 μm, i.e., if the through wire has a length of 50 μm. This value corresponds to a parasitic capacitance associated with an in-plane wire of 2 mm or longer from the fact that generally used in-plane wires produces a parasitic capacitance of approximately 0.2 pF per millimeter.

In a three-dimensional semiconductor device, wires must be laid out using in-plane wires and inter-chip wires in order to distribute signals to circuits formed in a plurality of semiconductor chips. For example, to operate all the circuits of a three-dimensional semiconductor device in synchronization, clock signal wires must be arranged for connection to all the circuits of the three-dimensional semiconductor device in order to distribute a clock signal from a clock generator circuit to each circuit. Also, when a three-dimensional semiconductor device is a multi-layer memory, memory cells that are to be accessed are distributed over the entire three-dimensional semiconductor device, so that data bus lines must be provided for transmitting and receiving data between an input/output buffer circuit for transmitting/receiving data to/from the outside and each memory cell. In either case, signals cannot be transmitted at high speeds because parasitic capacitances of wires must be charged and discharged each time a signal is transmitted. Also, there is another problem that power consumption increases in proportion to the parasitic capacitance of the wires. Accordingly, the parasitic capacitance of the wires is preferably as small as possible.

To reduce the parasitic capacitance of a wire, according to one method, insulating film 6 may be formed around the through wire in a larger thickness than a value (for example, 250 nm) typically used in DRAM and the like. However, since the step of forming insulating film 6 made of SiO₂ or the like on the side surface of a throughhole in a semiconductor substrate is performed after transistors and the like have been formed on semiconductor chips, process-related restrictions are imposed to the formation of insulating film 6. Specifically, the semiconductor chip cannot be placed in a high-temperature environment for a long time because impurities in the source and drain diffuse to cause a change in transistor characteristics. Thus, the formation of insulating film 6 made of SiO₂ cannot rely on a generally used thermal oxidation method, resulting in difficulties in forming a thick insulating film on the side surface of the throughhole with a high quality. While the insulating film may be formed by another method, for example, a sputtering method to vapor deposit the insulating film, atoms must be directed obliquely into the throughhole for vapor depositing the insulating film on the side surface of the throughhole which is located deep in the substrate as compared with an opening in the substrate, so that this method also fails to form a thick insulating film.

In the following, as illustrated in FIG. 3, a description will be given of a parasitic capacitance of wires in the entire exemplary three-dimensional semiconductor device (hereinafter called the “total three-dimensional wiring capacitance”) which has eight semiconductor chips 8 stacked on a semiconductor chip (interface chip 7) for interfacing with the outside. Assume in the three-dimensional semiconductor device illustrated in FIG. 3 that each semiconductor chip 8 is divided into 32 sub-circuit areas 9 (horizontally eight and vertically four), and signals are distributed to each of the 32 sub-circuit areas 9. Assume also that, as to dimensions, each semiconductor chip 8 is 20 mm wide, 10 mm long, and 50 μm thick.

As illustrated in FIG. 3, to distribute signals from buffer circuit 10 disposed at a corner of interface chip 7 to each of sub-circuit areas 9 of all semiconductor chips 8, there may be an in-plane wiring method which involves connecting all semiconductor chips 9 using a single through wire (inter-chip wire 11), and distributing signals to each of sub-circuit areas 9 in each semiconductor chip 8 using in-plane wires 2, as illustrated in FIG. 4A, and these may be an inter-chip wiring method which involves distributing signals to corresponding positions of respective sub-circuit areas 9 in interface chip 7, using the in-plane wires, and distributing signals from interface chip 7 to all semiconductor chips 8 using 32 through wires, as illustrated in FIG. 4B.

Semiconductor chip 8 illustrated in FIG. 3 has a long in-plane wire because one side thereof has a length of 10 mm or more, but has an inter-chip wire length as short as 50 μm because it is equal to the thickness of the semiconductor chip. Therefore, the inter-chip wiring method, which uses a large number of through wires, only requires a short wire length, and a low resistance value per unit length.

However, the inter-chip wiring method is disadvantageous for high-speed signal transmission because the total three-dimensional wiring capacitance is large due to the large number of through wires. A graph in FIG. 5 shows the relationship between the total three-dimensional wiring capacitance of the in-plane wiring method and the total three-dimensional wiring capacitance of the inter-chip wiring method with respect to the parasitic capacitance of the through wire (through wire capacitance). Specifically, FIG. 5 shows values of the total three-dimensional wiring capacitances of the in-plane wiring method and inter-chip wiring method, when the parasitic capacitance for each through wire (for one chip, i.e., 50 μm long) is changed on the assumption that the parasitic capacitance of the in-plane wire is 0.2 pF per 1 mm.

As shown in FIG. 5, in the inter-chip wiring method, the total three-dimensional wiring capacitance varies largely depending on the through wire capacitance because a large number of through wires are used. On the other hand, in the in-plane wiring method, the total three-dimensional capacitance varies within the capacitance of one through wire because only one through wire is used.

The in-plane wiring method which entails a large number of long in-plane wires exhibits a larger total three-dimensional wiring capacity when the through wire capacitance is smaller than 0.5 pF, whereas the inter-chip wiring method which entails a large number of through wires exhibits a larger total three-dimensional wiring capacitance when the through wire capacitance exceeds 0.5 pF. In particular, as branches within the plane increase so that a larger number of inter-chip wires are required, the total three-dimensional wiring capacitance of the inter-chip wiring method further varies largely depending on the through wire capacitance.

Accordingly, the three-dimensional semiconductor device illustrated in FIG. 3 preferably employs through wires having a small wire length and a small resistance value per unit length for inter-chip wires, and reduces the parasitic capacitance of the through wires as much as possible. However, as described above, difficulties have been experienced in reducing the parasitic capacitance due to the large cross-sectional area of through wires used for inter-chip wiring.

Generally, insulation is established by using an insulating film between a substrate and wires which include not only the through wire extending from the top surface to the bottom surface of a semiconductor substrate but also a current path (wire), through which a signal current flows, formed in the semiconductor substrate, for example, a wire embedded in a groove or a hole formed in the semiconductor substrate. Therefore, even in the foregoing configuration, a large parasitic capacitance is also produced between the wire and the semiconductor substrate, giving rise to problems of an inability to transmit signals at high speeds and an increase in power consumption during signal transmission.

### SUMMARY OF THE INVENTION

It is therefore an object of the present invention to provide a semiconductor chip and a semiconductor device which are capable of reducing the parasitic capacitance between a wire and a semiconductor substrate to transmit signals at higher speeds and prevent an increase in power consumption during signal transmission.

To achieve the above object, a wire embedded in a semiconductor substrate is covered with an insulating film, and a bias voltage is applied to the semiconductor substrate or to the wire to form a depletion layer extending from an edge of the insulating film within the semiconductor substrate.

Alternatively, a semiconductor layer having a different conductivity type from the semiconductor substrate is formed within the semiconductor substrate to surround the insulating film.

In the configuration as described above, since the depletion layer is formed within the semiconductor substrate from the edge of the insulating film, the parasitic capacitance of the wire is reduced by the capacitance of the depletion layer which is connected in series with the parasitic capacitance between the wire and the semiconductor substrate. Consequently, signals are transmitted through the wire at higher speeds, and an increase in power consumption during signal transmission can be prevented.

The above and other objects, features, and advantages of the present invention will become apparent from the following description with reference to the accompanying drawings which illustrate examples of the present invention.

### BRIEF DESCRIPTION OF THE DRAWINGS

FIG. 1 is a side sectional elevation illustrating an exemplary configuration of a three-dimensional semiconductor device;

FIG. 2 is a schematic diagram illustrating a through wire which is surrounded by the three-dimensional semiconductor device illustrated in FIG. 1;

FIG. 3 is a perspective view illustrating another exemplary configuration of a three-dimensional semiconductor device;

FIG. 4A is a perspective view illustrating a wiring layout of an in-plane wiring method for the three-dimensional semiconductor device illustrated in FIG. 3;

FIG. 4B is a perspective view illustrating a wiring layout of an inter-chip wiring method for the three-dimensional semiconductor device illustrated in FIG. 3;

FIG. 5 is a graph showing the relationship between the total three-dimensional wiring capacitance of the in-plane wiring method illustrated in FIG. 4A and the total three-dimensional wiring capacitance of the inter-chip wiring method illustrated in FIG. 4B with respect to the parasitic capacitance of a through wire;

FIG. 6 is a schematic diagram illustrating the configuration of a first embodiment of a semiconductor device according to the present invention;

FIG. 7 is a schematic diagram showing the energy band structure of the semiconductor device illustrated in FIG. 6;

FIG. 8 is a schematic diagram showing the configuration of the parasitic capacitance of a through wire included in the semiconductor device illustrated in FIG. 6;

FIG. 9 is a graph showing the result of a calculation for a change in the thickness of a depletion layer to a change in the bias voltage applied to a substrate of the semiconductor device illustrated in FIG. 6;

FIG. 10 is a graph showing the result of a calculation for a change in the capacitance ratio C/C0 to a change in the bias voltage applied to the substrate of the semiconductor device illustrated in FIG. 6;

FIG. 11 is a schematic diagram illustrating the configuration of a second embodiment of the semiconductor device according to the present invention;

FIG. 12 is a schematic diagram showing the configuration of the parasitic capacitance of a through wire included in the semiconductor device illustrated in FIG. 11;

FIG. 13 is a graph showing the result of a calculation for a change in the thickness of a depletion layer to a change in the density of an n-type impurity in a semiconductor layer included in the semiconductor device illustrated in FIG. 11;

FIG. 14 is a graph showing the result of a calculation for a change in the capacitance ratio C/C0 of a through wire to a change in the density of the n-type impurity in the semiconductor layer included in the semiconductor device illustrated in FIG. 11;

FIG. 15 is a cross-sectional view illustrating the configuration of a first exemplary implementation of the semiconductor device according to the present invention;

FIG. 16 is a side sectional elevation illustrating the structure around a through wire included in a memory cell array chip illustrated in FIG. 15;

FIG. 17 is a circuit diagram illustrating an exemplary configuration of a voltage generator circuit included in the semiconductor device illustrated in FIG. 15;

FIG. 18 is a plan view illustrating an exemplary configuration of a memory cell array chip included in the semiconductor device illustrated in FIG. 15;

FIG. 19 is a side sectional elevation illustrating the configuration of a third exemplary implementation of the semiconductor device according to the present invention;

FIG. 20 is a side sectional elevation illustrating the configuration of a fourth exemplary implementation of the semiconductor device according to the present invention; and

FIG. 21 is a side sectional elevation illustrating another configuration of the fourth exemplary implementation of the semiconductor device according to the present invention.

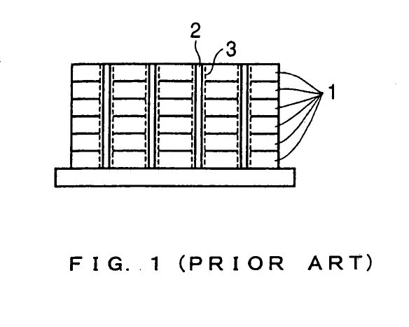

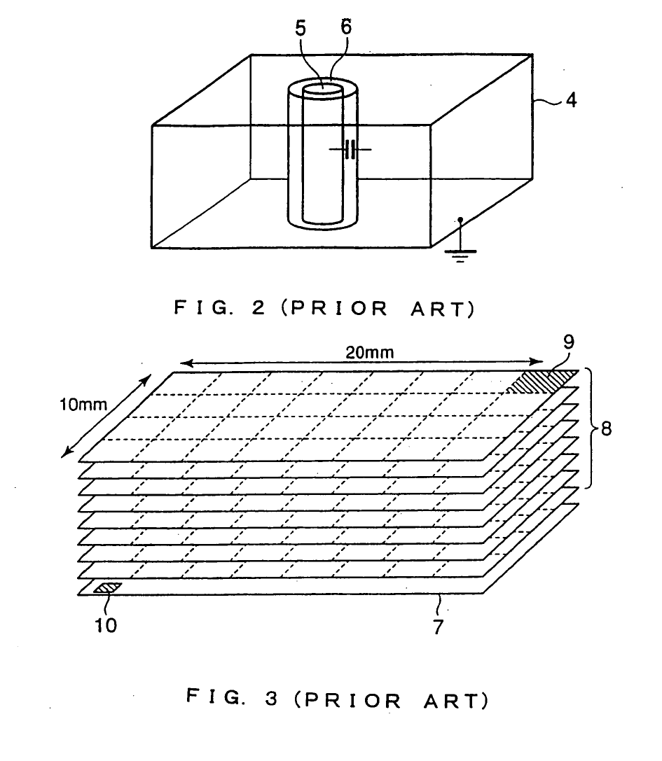

### DETAILED DESCRIPTION OF THE PREFERRED EMBODIMENTS

### First Embodiment

First, a description will be given of a first embodiment of a semiconductor device according to the present invention.

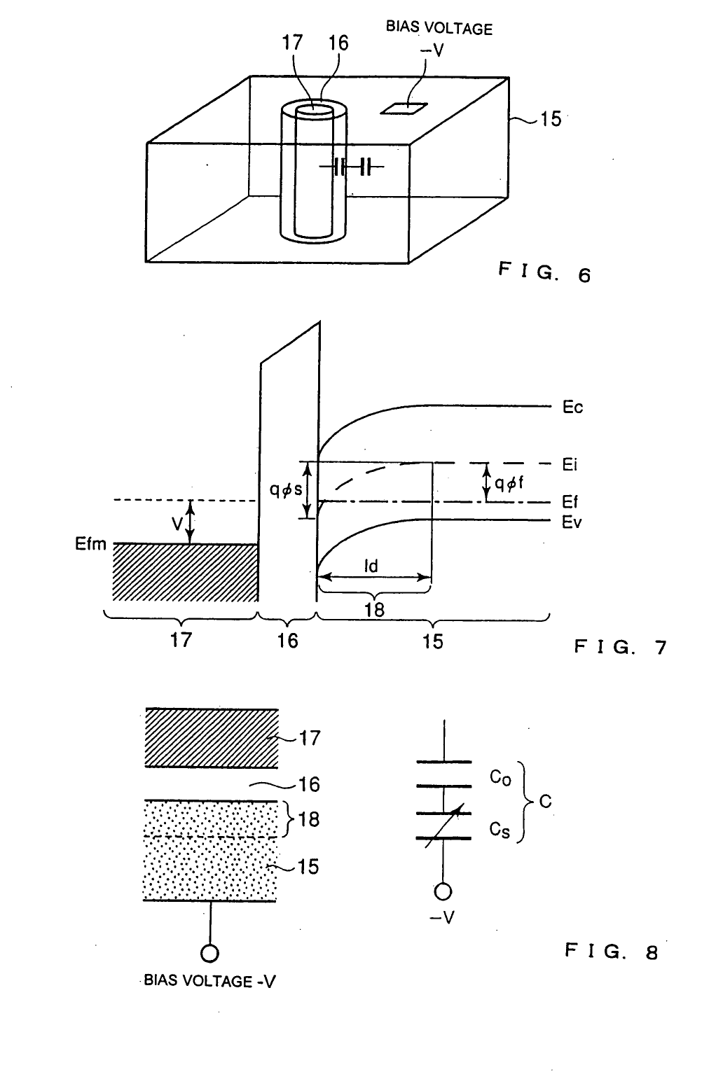

In the first embodiment, consider that Si semiconductor substrate (hereinafter simply called “substrate”) 15 made of a p-type semiconductor is applied with a negative bias voltage −V in a structure in which through wire 17 made of a metal is embedded in substrate 15 with insulating film 16 sandwiched therebetween, as illustrated in FIG. 6. In such a configuration, as shown in the energy band diagram of FIG. 7, surface potential øₛ is formed on the interface between substrate 15 and insulating film 16, and depletion layer 18 is formed within substrate 15. Efm shown in FIG. 7 represents the Fermi energy of the metal used for through wire 17; Ec the conduction band end energy of the p-type semiconductor used for substrate 15; Ev the valence band end energy of the p-type semiconductor used for substrate 15; Ef the Fermi energy of the p-type semiconductor used for substrate 15; and Ei the energy at the center of the band gap.

In this event, thickness Iₚ of depletion layer 18 is expressed by the following equations:
when 0<øₛ<2ø_{f}:

$${l}_{D} = \frac{K {ɛ}_{0}}{{C}_{0}} ( \sqrt{1 + \frac{2 {C}_{0}^{2} V}{K {ɛ}_{0 q} {N}_{a}} - 1} ) ,$$

when øₛ≦2ø_{f}:

$${l}_{D} = \sqrt{\frac{2 K {ɛ}_{0} ( 2 {ϕ}_{f} )}{{qN}_{a}}}$$

where K represents the relative dielectric constant of substrate 15; ε₀ the dielectric constant of vacuum; C₀ a parasitic capacitance between through wire 17 and substrate 15 formed across insulating film 16; q a charge amount of electron; and Na the density of a p-type impurity which is an acceptor.

Also, Fermi potential ø_{f} is expressed by the following equation:

$${ϕ}_{f} = \frac{kT}{q} ln \frac{Na}{{n}_{i}}$$

where nᵢ represents the density of the intrinsic carrier of the p-type semiconductor (substrate 15).

When depletion layer 18 is formed, the total parasitic capacitance C of the through wire is equal to a value resulting from the series connection of parasitic capacitance C₀ between through wire 17 and substrate 15 having capacitance C_{S} of depletion layer 18, as shown in FIG. 8, and expressed as follows:

$$\frac{1}{C} = \frac{1}{{C}_{0}} + \frac{1}{{C}_{S}}$$

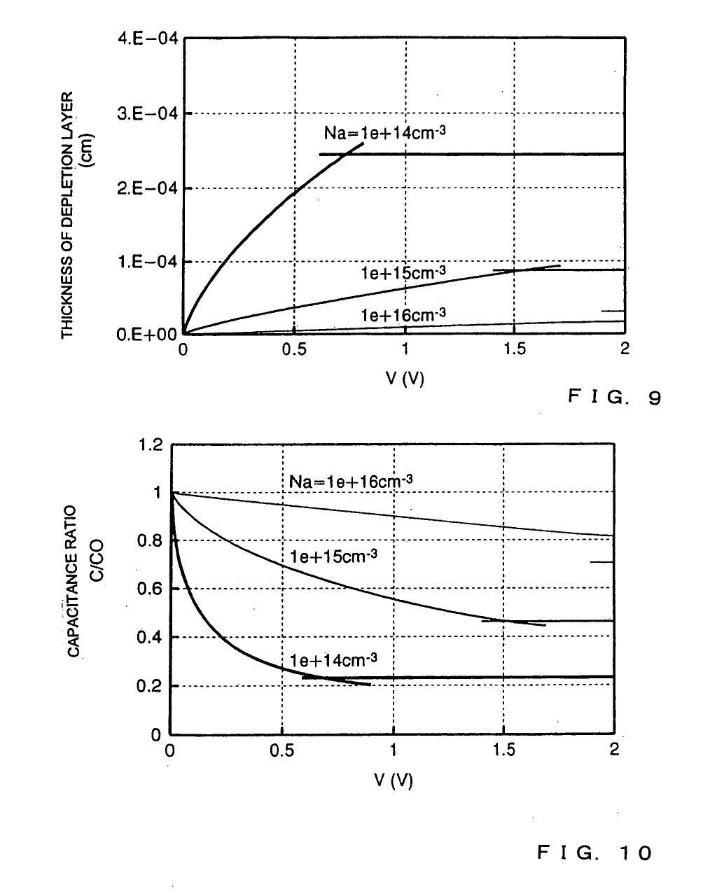

A graph shown in FIG. 9 shows the result of calculating a change in the thickness of the depletion layer to a change in the bias voltage (−V) applied to each of substrates (Si) which differ in p-type impurity (Na) from one another.

As can be seen from the graph of FIG. 9, when a constant bias voltage is applied to the substrate, the depletion layer becomes thicker as the p-type impurity density is reduced, whereas at any density, the thickness of the depletion layer increases as the absolute value of the bias voltage applied to the substrate is increased. However, when the bias voltage applied to the substrate exceeds a predetermined voltage, and øₛ is equal to or larger than 2ø_{f}, an inversion layer is formed on the interface between the insulating film and the substrate, and since charges are accumulated in this inversion layer, the depletion layer no longer increases in thickness but remains constant.

The graph shown in FIG. 10 shows the result of calculating a change in the capacitance ratio C/C0 to a change in the bias voltage (−V) applied to each of the substrates (Si) which differ in p-type impurity density (Na) from one another, where C0 represents the parasitic capacitance of a through wire when the substrate is applied with no bias voltage; and where C represents the parasitic capacitance of the through wire when the substrate is applied with the bias voltage.

As can be seen from the graph of FIG. 10, when the p-type impurity density of the substrate is, for example, 1×10¹⁵ cm⁻³, the parasitic capacitance of the through wire, when the substrate is applied with the bias voltage of −1 volt, is reduced to approximately 50% of that when the substrate is not applied with the bias voltage.

Consequently, a signal is transmitted through the through wire at high speeds, and an increase in power consumption during signal transmission can be prevented.

While the foregoing embodiment has been described in connection with an example in which a p-type semiconductor substrate is applied with a negative bias voltage, the foregoing description is applied, as well, when the through wire is applied with a positive bias voltage. Also, when an n-type semiconductor substrate is used, a depletion layer is formed in a similar manner either when the n-type semiconductor substrate is applied with a positive bias voltage or when the through wire is applied with a negative bias voltage.

### Second Embodiment

Next, a description will be given of a second embodiment of the semiconductor device according to the present invention.

As illustrated in FIG. 11, as insulating film 21 is formed on the side surface of a throughhole in which through wire 22 is to be embedded, and semiconductor layer 20 whose conductivity type is opposite to that of substrate 19 is formed around insulating film 21 by an ion implantation method, and a p-n junction having a depletion layer is formed on the interface between substrate 19 and semiconductor layer 20.

In the configuration as described above, the parasitic capacitance C of through wire 22 is also equal to the value resulting from a series connection of parasitic capacitance C₀ between substrate 19 and through wire 22 and capacitance C_{S} of depletion layer 23, as shown in FIG. 12. Depletion layer 23 formed on this p-n junction interface has thickness Id which is expressed by the following equation:

$${l}_{d} = \sqrt{\frac{2 K {ɛ}_{0}}{q} \cdot \frac{{N}_{a} + {N}_{d}}{{N}_{a} {N}_{d}} {ϕ}_{bi}}$$

where Nd represents the density of an n-type impurity which is a donor.

Also, built-in potential ø_{bi} on the p-n junction interface is expressed by the following equation:

$${ϕ}_{bi} = \frac{kT}{q} ln \frac{{N}_{a} {N}_{d}}{{n}_{i}^{2}}$$

where k represents the Boltzmann constant, and T the ambient temperature.

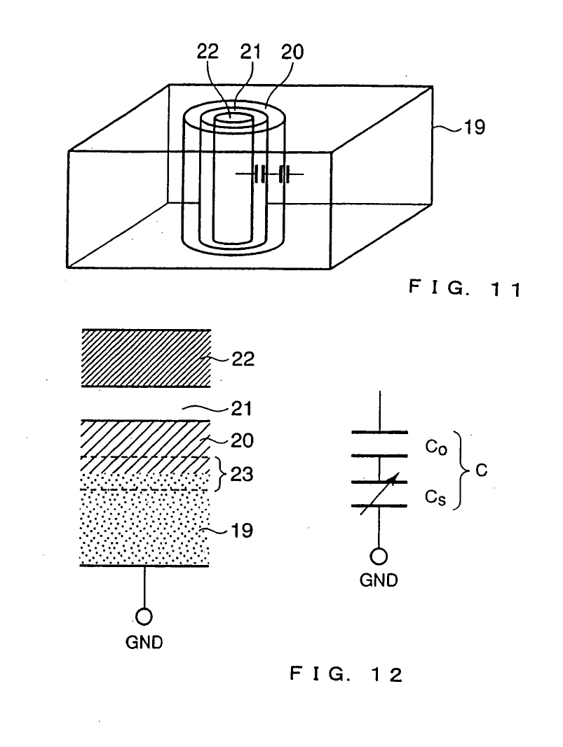

A graph shown in FIG. 13 plots the result of a calculation for a change in the thickness of the depletion layer to a change in the n-type impurity density (Nd) in semiconductor layer 20 when the p-n junction is formed by injecting an n-type impurity into each of the substrates which differ in p-type impurity density. As can be seen from the graph of FIG. 13, the depletion layer formed on the interface of the p-n junction is formed thicker as the n-type impurity density becomes lower.

A graph shown in FIG. 14 plots the result of a calculation for a change in the capacitance ratio C/C0 of the through wire to a change in the n-type impurity density (Nd) in semiconductor layer 20 when the p-n junction is formed by injecting an n-type impurity into each of the substrates which differ in p-type impurity density, where C0 represents the parasitic capacitance of the through wire when no n-type impurity is injected, and C represents the parasitic capacitance of the through wire when the n-type impurity is injected.

As can be seen from the graph of FIG. 14, when the p-type impurity density of the substrate is set, for example, at 1×10¹⁴ cm⁻³, the parasitic capacitance of the through wire, when the n-type impurity is injected, decreases to approximately 20% of that when no n-type impurity is injected.

As described above, since the depletion layer is formed near the edge of the insulating film within the substrate by applying a bias voltage to the substrate or to the through wire or by forming the p-n junction around the through wire, the parasitic capacitance of the wire decreases by the amount of capacitance of the depletion layer connected in series with the parasitic capacitance between the wire and the substrate.

Consequently, signals are transmitted through the through wire at higher speeds, and an increase in power consumption during signal transmission can be prevented.

The semiconductor devices in the first and second embodiments can be used not only with a through wire which extends from the top surface to the bottom surface of a substrate, but also with a configuration formed with a wire (current path) embedded, for example, in a groove or a hole formed in a substrate through an insulating film for carrying a signal current therethrough.

(First Exemplary Implementation)

In a semiconductor device in a first exemplary implementation, a depletion layer is formed within the substrate from the edge of an insulating film by applying a bias voltage to the substrate in which a through wire is embedded through the insulating layer, as illustrated in FIG. 6, and the depletion layer is used to reduce the parasitic capacitance of the through wire.

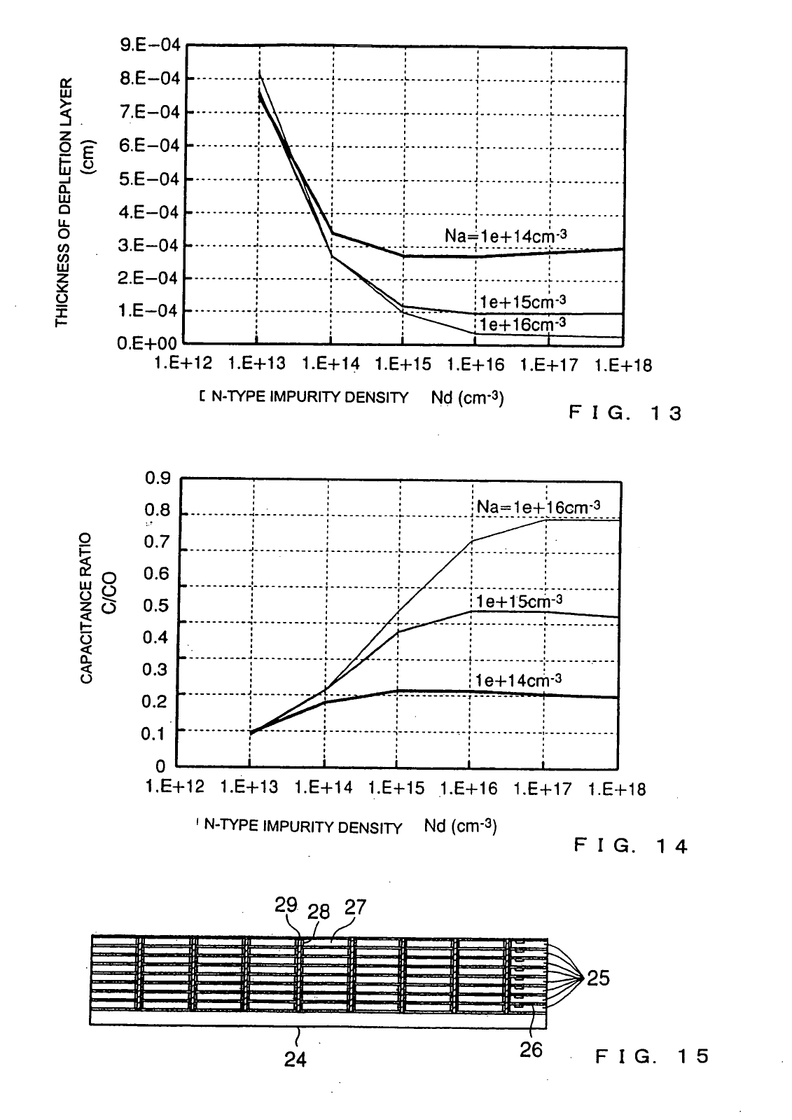

FIG. 15 is a side sectional elevation illustrating the configuration of the first exemplary implementation of the semiconductor device according to the present invention.

As illustrated in FIG. 15, the semiconductor device in the first exemplary implementation comprises eight memory cell array chips 25 stacked on interface chip 24, which is a semiconductor chip for interfacing with the outside, with interlayer insulating layers 26 sandwiched between respective memory cell array chips 25.

Each memory cell array chip 25 comprises a memory cell array formed in substrate 27 which has a p-type impurity density on the order of 1×10¹⁵ cm⁻³. As to dimensions, each chip 25 is 20 mm wide, 10 mm long, and 50 μm thick. Interface chip 24 and each memory cell array chip 25, and respective memory cell array chips 25 are interconnected through through wires 29 formed within through holes in substrate 27 with insulating film 28 sandwiched therebetween.

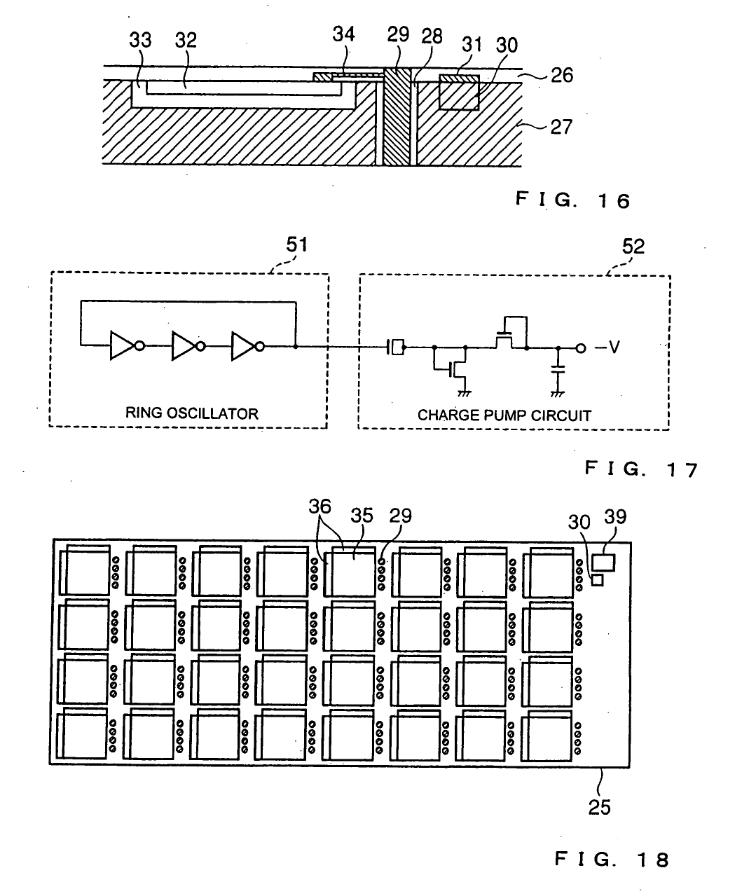

FIG. 16 is a side sectional elevation illustrating the structure around the through wire included in the memory array chip shown in FIG. 15.

As illustrated in FIG. 16, a throughhole of substrate 27 is embedded with through wire 29 which has a diameter of approximately 20 μm and insulating film 28 approximately 250 nm thick, made of SiO₂, for example, sandwiched therebetween. A metal (Cu) or polysilicon or the like is used for through wire 29.

P-type diffusion region 30 is formed near the surface of substrate 27 at an impurity density of approximately 1×10¹⁸ cm⁻³, and electrode 31 is formed on p-type diffusion region 30 for applying a bias voltage to substrate 27. Electrode 31 is applied with a negative (−) bias voltage from voltage generator circuit 39 (see FIG. 18) formed on each memory cell array chip 25. Voltage generator circuit 39 may be comprised, for example, of well-known ring oscillator 51 and charge pump circuit 52 shown in FIG. 17.

By applying substrate 27 with a bias voltage through electrode 31 and p-type diffusion region 30, a negative potential prevails over all regions including the surrounding area of the through wire, indicated by hatching in FIG. 16. However, since memory cell array 32 formed on the surface of the substrate is formed on buried layer 33 made of an n-type semiconductor, memory cell array 32 is electrically isolated from substrate 27 which is set at the negative potential by the bias voltage. Memory cell array 32 and through wire 29 are interconnected by in-plane wires 34. When memory cell array 32 is applied with a negative bias voltage, buried layer 33 made of an n-type semiconductor is not needed.

As illustrated in FIG. 18, memory cell array chip 25 has, for example, 32 sub-memory arrays 35, each of which is provided with row address and column address decoder 36. Sub-memory array 35 has an input/output bit length of four bits, for example, and sub-memory array 35 is connected to an input/output buffer formed on interface chip 24 using four through wires 29 which serve as data lines. Therefore, there are 128 through wires 29 per chip for data lines.

In the configuration as described above, when no bias voltage is applied to substrate 27, one through wire 29 produces a parasitic capacitance of approximately 0.45 pF in one memory cell array chip 25. On the other hand, when substrate 27 is applied with a bias voltage of −1 volt, a depletion layer of 0.62 μm thick is formed within the substrate from the edge of insulating film 28. Since the capacitance exhibited by this depletion layer is connected in series with the parasitic capacitance between through wire 29 and substrate 27, the parasitic capacitance of through wire 29 decreases to 0.24 pF which is approximately 0.54 times as much as the original value (see FIG. 10).

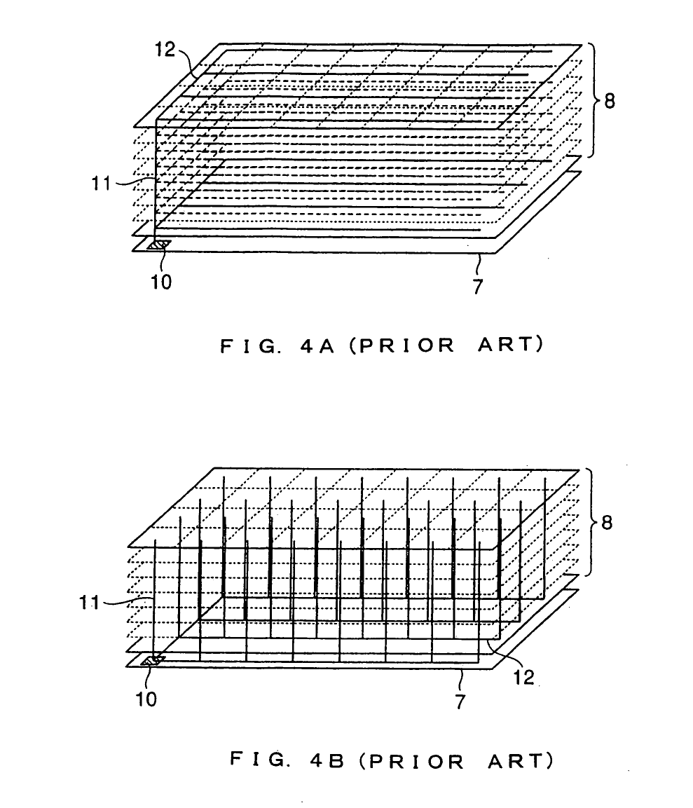

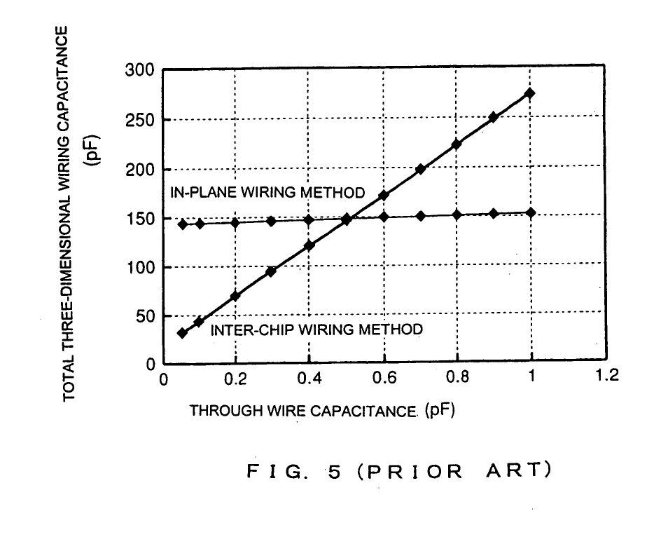

Therefore, when data lines are arranged using through wires 29, for example, in accordance with the inter-chip wiring method illustrated in FIG. 4B, the total parasitic capacitance of the data lines amounts to 133 pF per bit when no bias voltage is applied to substrate 27 (see FIG. 5). In contrast, in the semiconductor device of this exemplary implementation, the total parasitic capacitance of the data lines amounts to 79 pF per bit by applying substrate 27 with a bias voltage of −1 volt, thus reducing the total parasitic capacitance by approximately 40%. Since the power consumed for charging and discharging the data lines during a signal transmission is proportional to the parasitic capacitance of wires, the power consumption for charging and discharging the data lines is reduced by 40%.

While the bias voltage applied to substrate 27 is set to −1 volt in the foregoing description, the depletion layer becomes thicker as the absolute value of the bias voltage is increased to increase the capacitance, resulting in a further reduction in the parasitic capacitance of the through wires. However, if the bias voltage exceeds −1.6 volts, an inversion layer is formed on the interface between insulating film 28 and substrate 27, so that the depletion layer will not grow further thicker.

Accordingly, when the bias voltage applied to substrate 27 is set to −1.6 volts at which the formation of the inversion layer begins, a depletion layer having the highest thickness can be formed, thus providing the largest effect for reducing the parasitic capacitance produced by applying the bias voltage to substrate 27.

According to the semiconductor device of this exemplary implementation, a device for applying a bias voltage to substrate 27 is provided to form a depletion layer near the edge of the insulating film within the substrate 27. Since the parasitic capacitance of the wire is reduced by the capacitance of the depletion layer connected in series with the parasitic capacitance between the wire and the substrate, signals are transmitted at higher speeds, and an increase in power consumption during signal transmission can be prevented.

As shown in the graph of FIG. 10, the semiconductor device of this exemplary implementation can further reduce the parasitic capacitance of the through wire by reducing the p-type impurity density of substrate 27. Generally, however, a lower impurity density would cause the characteristics of substrate 27 to be closer to that of an insulating material, resulting in an unstable substrate potential. Therefore, an excessive reduction in impurity density is not preferred. Generally, a lower limit for the p-type impurity density of substrate 27 is approximately 1×10¹⁴ cm⁻³, at which the parasitic capacitance of the through wire, when a bias voltage is applied, can be reduced to approximately 20% of that when no bias voltage is applied.

On the other hand, the parasitic capacitance of through wire 29 can be reduced by increasing the absolute value of a bias voltage applied to substrate 27, but the use of a bias voltage higher than a supply voltage used in a circuit formed on substrate 27 is not preferred because a large amount of power is consumed when the bias voltage is generated.

Approximately −2 volts are sufficient at most for the bias voltage applied to substrate 27 judging from the fact that the inversion layer can be formed as described above. For example, when a bias voltage of −2 volts is applied to substrate 27 having a p-type impurity density of 1×10¹⁶ cm⁻³, the parasitic capacitance of through wire 29 is reduced to approximately 80% of that when no bias voltage is applied.

Consequently, the relationship between the impurity density of substrate 27 and the bias voltage is preferably set such that the aforementioned capacitance ratio C/C0 remains within a range of 0.2 to 0.8.

The ratio V/Na of the bias voltage to the impurity density of the substrate is expressed by the following equation:

$$\frac{V}{Na} = \frac{K {ɛ}_{0} q}{2 {C}_{0}^{2}} ( \frac{{C}_{0}^{2}}{{C}^{2}} - 1 )$$

where the value of V/Na which satisfies:

$$0.2 \leq \frac{C}{{C}_{0}} \leq 0.8$$

is equal to or more than 2.3×10⁻¹⁶ (V/cm⁻³) and equal to or less than 9.9×10⁻¹⁵ (V/cm⁻³).

Thus, even in consideration of the fact that the conductivity type of the substrate becomes the p-type or n-type depending on the type of impurity, the ratio of the absolute value of the bias voltage applied to the substrate to the impurity density of the substrate applied with the bias voltage is preferably equal to or more than 2.3×10⁻¹⁶ (V/cm⁻³) and equal to or less than 9.9×10⁻¹⁵ (V/cm⁻³).

While the foregoing exemplary implementation has shown an exemplary semiconductor device which comprises voltage generator circuit 39 for generating a bias voltage in all memory cell array chips 25 such that a bias voltage applied to substrate 27 is generated in each of memory cell array chips 25, voltage generator circuit 39 may be provided only in one of a plurality of stacked memory cell array chips 25 such that a bias voltage generated by voltage generator circuit 39 is supplied to all other memory cell array chips 25 using dedicated through wires. Further, the interface chip may comprise a terminal for supplying a bias voltage from the outside, such that the bias voltage supplied from this terminal is supplied to substrate 27 of each memory cell array chip 25.

Also, while the foregoing exemplary implementation has been described in connection with substrate 27 which has p-type conductivity by way of example, substrate 27 having n-type conductivity may be applied with a positive (+) bias voltage to form a depletion layer near the interface between insulating film 28 and substrate 27 in a manner similar to the foregoing. Also, while the foregoing exemplary implementation has been described in connection with memory cell array chips 25 which are stacked semiconductor chips, by way of example, circuits formed on semiconductor chips may be CPU, DSP, or other logic circuits, and any semiconductor chip having any type of circuit can reduce the parasitic capacitance of a wire by applying a bias voltage to its substrate, as is done in this exemplary implementation.

Also, while the foregoing exemplary implementation has shown, by way of example, that substrate 27 is intentionally applied with a bias voltage, a potential difference can be produced between through wire 29 and substrate 27 due to current leakage from circuits formed on substrate 27 and the like when the potential on substrate 27 is not fixed, or when substrate 27 is coupled to a fixed potential through a resistor having a relatively large resistance. In this exemplary implementation, since similar effects can be provided only if a potential difference is produced between through wire 29 and substrate 27, a device for applying a bias voltage may be in any configuration, and the potential difference produced between through wire 29 and substrate 27 due to leakage current from circuits formed on substrate 27 and the like, as described above, is also included in the device for applying a bias voltage.

(Second Exemplary Implementation)

The semiconductor device of the first exemplary implementation is an example of forming a depletion layer near the interface between through wire 29 and insulating film 28 within substrate 27 by applying a bias voltage to substrate 27 in which through wire 29 is formed, to produce a potential difference between through wire 29 and substrate 27.

A semiconductor device of a second exemplary implementation involves applying a bias voltage to through wire 29 (or multiplexing a bias voltage on a signal) to produce a potential difference between through wire 29 and substrate 27, thereby forming a depletion layer near the edge of insulating film within substrate 27. Since the semiconductor device is similar in configuration to that of the first exemplary implementation, a description thereon is omitted.

For example, in memory cell array chip 25 illustrated in FIG. 18, a clock signal is distributed from a clock driver circuit formed in interface chip 24 to decoders 36 included in respective sub-memory arrays 35. Here, assuming that the supply voltage is 1.8 volts and the clock frequency is 200 MHz, the supplied clock signal has a high voltage at 1.8 volts, a low voltage at 0 volt, and a duty ratio of high duration to low duration equal to 50%.

The following description will be given of an example which employs a through wire whose size is the same as the data lines, shown in the first exemplary implementation, of a clock line for transmitting the clock signal. Assume that substrate 27 is applied with a bias voltage of −1 volt as is the case with the first exemplary implementation.

In the semiconductor device of this exemplary implementation, a potential difference is produced between through wire 29 and substrate 27 by applying a bias voltage to through wire 29. Specifically, a bias voltage of +0.5 volts is applied to through wire 29 by pulling a signal line up (or down) to a predetermined voltage by using a resistor or the like to distribute a clock signal to each sub-memory array 35. The clock signal has a high voltage at 2.3 volts and a low voltage at 0.5 volts. As through wire 29 is applied with the bias voltage of +0.5 volts in this manner, together with the bias voltage (−1 volt) applied to substrate 27, an intentional potential difference of 1.5 volts can be produced between through wire 29 and substrate 27.

In such a configuration, a depletion layer of 0.84 μm thick is also formed within the substrate 27 from the edge of insulating film 28. Since the capacitance of this depletion layer is connected in series with the parasitic capacitance (0.45 pF) of through wire 29, the parasitic capacitance of through wire 29 is reduced to 0.21 pF, i.e., 0.46 times the original value.

Accordingly, when a clock line is routed, using through wire 29, for example, in accordance with the inter-chip wiring method illustrated in FIG. 4B, the total parasitic capacitance of the data line amounts to 133 pF per bit when no bias voltage is applied to through wire 29 or to substrate 27 (see FIG. 5). In contrast, in the semiconductor device of this exemplary implementation, the total parasitic capacitance of the clock line is reduced to 72 pF by multiplexing a bias voltage of 0.5 volts to through wire 29.

According to the semiconductor device of this exemplary implementation, a device for applying a bias voltage to through wire 29 is provided to form a depletion layer near the edge of insulating film 28 within the substrate 27, in a manner similar to the first exemplary implementation. Since the parasitic capacitance of through wire 29 is reduced by the capacitance of the depletion layer connected in series with the parasitic capacitance between through wire 29 and substrate 27, signals are transmitted at higher speeds, and an increase in power consumption during signal transmission can be prevented.

While the foregoing description has shown an example of producing a potential difference between substrate 27 and through wire 29 by applying a bias voltage of +0.5 volts to through wire 29, the bias voltage applied to through wire 29 may be set such that the potential difference between substrate 27 and through wire 29 reaches 1.6 volts at which point the formation of an inversion layer begins, as in the first exemplary implementation, resulting in the formation of a depletion layer having the highest thickness, in which case the greatest effect that can be produced for reducing the parasitic capacitance is by applying the bias voltage to through wire 29.

Likewise as in the first exemplary implementation, the semiconductor device of the second exemplary implementation preferably exhibits the ratio of the absolute value of the potential difference between through wire 29 and substrate 27 to the impurity density of substrate 27 equal to or more than 2.3×10⁻¹⁶ (V/cm⁻³) and equal to or less than 9.9×10⁻¹⁵ (V/cm⁻³).

The wires applied with a bias voltage need not be all wires which are fed with signals, but the bias voltage may be applied to only those wires which are applied, for example, with relatively fast signals. In this event, since the current output capabilities of a circuit for generating a bias voltage can be reduced in, the circuit can be manufactured at a lower cost.

Also, while the foregoing exemplary implementation has shown the application of a bias voltage to through wire 29, by way of example, the bias voltage may be multiplexed on a signal by controlling the average of signal voltages by changing, for example, the duty ratio or the amplitude value. This multiplexing is equivalent to the application of the bias voltage to through wire 29. In this exemplary implementation, since similar effects are provided only if a potential difference is produced between through wire 29 and substrate 27, any device may be employed for applying a bias voltage to through wire 29, and a feature for controlling the duty ratio or the amplitude value of a signal as described above is also included in the device for applying a bias voltage. Further alternatively, a signal multiplexed with a bias voltage may be applied from the outside to produce a potential difference between through wire 29 and substrate 27. In this event, the bias voltage may not be multiplexed at all times but may be multiplexed only when a fast signal, for example, is applied. However, an excessively increased signal amplitude would increase charge/discharge currents in the parasitic capacitance, resulting in an increase in consumed current and a failure in transmitting signals at high speeds. It is therefore more preferably that the signal is restrained in amplitude as much as possible, and a bias voltage is applied from the outside.

Also, the foregoing exemplary implementation has been described in connection with substrate 27 which has p-type conductivity, by way of example. With substrate 27 having n-type conductivity, a negative (−) bias voltage may be multiplexed on a signal to form a depletion layer near the edge of insulating film 28 in a manner similar to the foregoing. As well, while the foregoing exemplary implementation has been described in connection with memory cell array chips 25 which are given as examples of stacked semiconductor chips, circuits formed on semiconductor chips may be CPU, DSP, or other logic circuits, and the parasitic capacitance of the wire can be reduced by multiplexing a bias voltage on a signal transmitted through the through wire as in the second exemplary implementation.

(Third Exemplary Implementation)

A semiconductor device of a third exemplary implementation involves forming a semiconductor layer of a conductivity type different from that of a substrate around an insulating film surrounding a through wire, as illustrated in FIG. 11, and utilizing a depletion layer of a p-n junction formed on the interface between the substrate and the semiconductor layer to reduce the parasitic capacitance of the through wire.

FIG. 19 is a side sectional elevation illustrating the configuration of the third exemplary implementation of the semiconductor device according to the present invention.

As illustrated in FIG. 19, the semiconductor device of the third exemplary implementation comprises eight memory cell array chips 41 stacked on interface chip 40, which is a semiconductor chip for interfacing with the outside, with interlayer insulating layers 42 sandwiched between respective memory cell array chips 41.

Each memory cell array chip 41 comprises a memory cell array formed on substrate 43 which has a p-type impurity density of approximately 1×10¹⁵ cm⁻³, and a thickness of 50 μm.

Interface chip 40 and each memory cell array chip 41, and respective memory cell array chips 41 are interconnected through through wires 45 each formed within a throughhole of substrate 43 with insulating film 44 sandwiched therebetween. Insulating film 44 made of SiO₂ has a thickness of approximately 250 nm, while through wire 45 is formed of a metal (Cu) or polysilicon having a diameter of approximately 20 μm in the cross section.

Semiconductor layer 46 is formed on a side surface of the throughhole pierced through substrate 43 using, for example, an ion implantation method, to have a depth of approximately 2.7 μm and an n-type impurity density of 1×10¹⁴ cm⁻³.

In such a configuration, a p-n junction is formed by substrate 43 and semiconductor layer 46 with a depletion layer formed on the junction interface therebetween. Here, the depletion layer is formed in n-type semiconductor layer 46 which is lower in impurity density, and almost all semiconductor layer 46 is depleted.

As described above, there is a parasitic capacitance of approximately 0.45 pF per through wire in one memory cell array chip. On the other hand, in this exemplary implementation, the depletion layer formed on the junction interface of the p-n junction helps reduce the parasitic capacitance of through wire 45 to 0.09 pF. Consequently, since the parasitic capacitance of the wire is reduced by the capacitance of the depletion layer formed on the junction interface of the p-n junction which is connected in series with the parasitic capacitance between the wire and the substrate, signals are transmitted at higher speeds, and an increase in power consumption during signal transmission can be prevented.

While the foregoing exemplary implementation has shown the formation of n-type semiconductor layer 46 on the side surface of the throughhole in substrate 43 using an ion implantation method by way of example, n-type semiconductor layer 46 may be grown in crystals by a vapor phase epitaxy method instead of the ion implantation method.

Also, substrate 43 of stacked memory cell array chips 41 may be applied with a bias voltage to feed a reverse bias across the p-n junction to form a yet thicker depletion layer.

Further, in the exemplary implementation described above, substrate 43 has p-type conductivity. When substrate 43 has n-type conductivity, a p-type semiconductor layer may be formed on the side surface of the throughhole, resulting in the formation of a p-n junction having a depletion layer on the interface between substrate 43 and semiconductor layer 46 in a manner similar to the foregoing. Also, while the foregoing exemplary implementation has been described in connection with memory cell array chips 41, by way of example, which are stacked semiconductor chips, circuits formed on semiconductor chips may be CPU, DSP, or other logic circuits, and the parasitic capacitance of the through wire can be reduced by multiplexing a bias voltage on a signal transmitted through the through wire as in the third exemplary implementation.

(Fourth Exemplary Implementation)

In the foregoing first to third exemplary implementations, the features of the present invention have been described giving, as an example, a through wire which extends from the top surface to the bottom surface of a substrate. A fourth exemplary implementation shows a wire embedded in a substrate to which the configurations of the first to third exemplary implementations are applied.

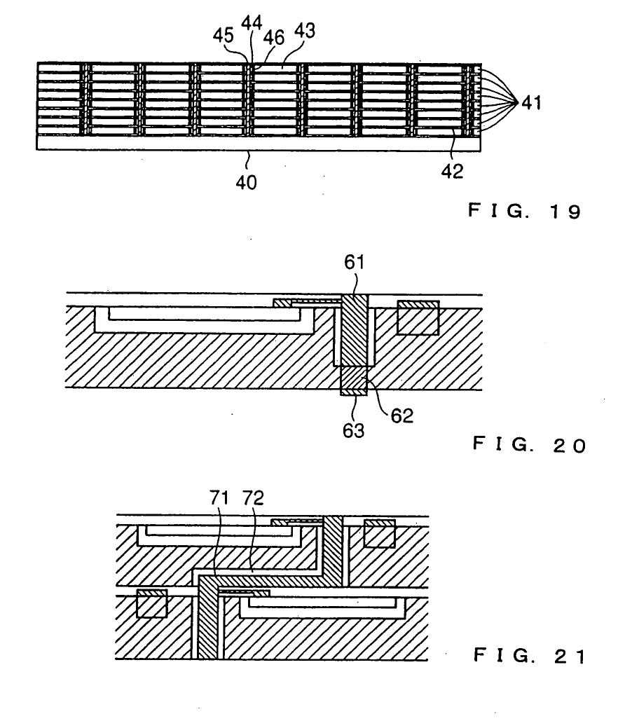

FIG. 20 is a side sectional elevation illustrating the configuration of the fourth exemplary implementation of the semiconductor device according to the present invention, and FIG. 21 is a side sectional elevation illustrating another configuration of the fourth exemplary implementation of the semiconductor device according to the present invention.

Either of FIG. 20 or 21 show an exemplary modification to the semiconductor device illustrated in FIG. 16. FIG. 20 shows a substrate having an opening on a surface thereof, into which a wire is embedded (embedded wire 61) made of a metal or polysilicon. High density n+ diffusion region 62 is formed on the bottom surface of the substrate opposite to buried wire 61 to form bottom electrode 63 across buried wire 61. In such a configuration, a current flows between embedded wire 61 and bottom electrode 63 through n+ diffusion region 62 with a predetermined resistance value.

FIG. 21 in turn illustrates an exemplary countermeasure which is taken in the event of a failure to align through wires arranged in two stacked substrates, wherein a wire (groove wire 72) is routed in a groove formed in one of the substrates horizontally to the surface thereof, thereby enabling a connection of the through wires to each other even if they are out of alignment.

Thus, when a bias voltage is applied to a substrate including buried wire 61, which does not extend from the top surface to the bottom surface thereof, or to groove wire 71 routed horizontally to the surface thereof, a depletion layer can also be formed near the edge of the insulating film around the wire within the substrate, in a manner similar to the first exemplary implementation, and the parasitic capacitance of the wire can be reduced by the capacitance of the depletion layer.

Also, a bias voltage may be multiplexed on the wire to produce a predetermined potential difference between the substrate and the wire, in a manner similar to the second exemplary implementation, to form a depletion layer that adjoins the insulating film surrounds the wire within the substrate, so that the parasitic capacitance of the wire can be reduced by the capacitance of the depletion layer.

Further, a semiconductor layer of a conductivity type different from that of the substrate may be formed around the wire, in a manner similar to the third exemplary implementation, to form a p-n junction having a depletion layer on the junction interface, so that the parasitic capacitance of the wire can be reduced by the capacitance of the depletion layer.

Consequently, signals are transmitted through the wire at higher speeds, and an increase in power consumption during signal transmission can be prevented.

While the first to fourth exemplary implementations have employed an SiO₂ film for the insulating film, the insulating film need not be made of SiO₂, but may be made of any material, for example, SiNx, TiO₂, Al₂O₃ and the like, as long as it has a relatively low dielectric constant.

Also, in the foregoing first to fourth exemplary implementations, the features of the present invention have been described in connection with exemplary semiconductor devices each having memory cell array chips stacked on an interface chip with interlayer insulating layers sandwiched between the respective memory cell array chips. However, the semiconductor device according to the present invention is not limited to a configuration having a plurality of stacked semiconductor chips, but can be applied to any configuration, for example, a configuration having only one semiconductor chip, a configuration having a plurality of semiconductor chips mixedly mounted on an interface chip, a configuration comprising a multi-layer structure which has a plurality of semiconductor chips stacked on an interface chip, and the like.

While a preferred embodiment of the present invention has been described using specific terms, such description is for illustrative purposes only, and it is to be understood that changes and variations may be made without departing from the spirit or scope of the following claims.

What is claimed is:

1. A semiconductor chip comprising:
a semiconductor substrate;
a wire having at least a portion thereof embedded in said semiconductor substrate and serving as a current path through which a current flows in response to a transmission signal;
an insulating layer for covering the portion of said wire embedded in said semiconductor substrate; and
a device for applying a bias voltage to said semiconductor substrate to form a depletion layer extending from an edge of said insulating film within said semiconductor substrate.

2. A semiconductor chip comprising:
a semiconductor substrate;
a wire having at least a portion thereof embedded in said semiconductor substrate and serving as a current path through which a current flows in response to a transmission signal;
an insulating layer for covering the portion of said wire embedded in said semiconductor substrate; and
a device for applying a bias voltage to said wire to form a depletion layer extending from an edge of said insulating film within said semiconductor substrate.

3. The semiconductor chip according to claim 1, wherein:
said bias voltage has a value at which an inversion layer is formed on an interface between said insulating film and said semiconductor substrate.

4. The semiconductor chip according to claim 2, wherein:
said bias voltage has a value at which an inversion layer is formed on an interface between said insulating film and said semiconductor substrate.

5. The semiconductor chip according to claim 1, wherein:
a ratio of an absolute value of the bias voltage to an impurity density of said semiconductor substrate is equal to or more than 2.3×10⁻¹⁶ (V/cm⁻³) and equal to or less than 9.9×10⁻¹⁵ (V/cm⁻³).

6. The semiconductor chip according to claim 2, wherein:
a ratio of an absolute value of the bias voltage to an impurity density of said semiconductor substrate is equal to or more than 2.3×10⁻¹⁶ (V/cm⁻³) and equal to or less than 9.9×10⁻¹⁵ (V/cm⁻³).

7. A semiconductor chip comprising:
a semiconductor substrate having a first conductivity type;
a wire having at least a portion thereof embedded in said semiconductor substrate and serving as a current path through which a current flows in response to a transmission signal;
an insulating layer for covering the portion of said wire embedded in said semiconductor substrate; and
a semiconductor layer having a second conductivity type different from the first conductivity type and formed within said semiconductor substrate to surround said insulating film.

8. The semiconductor chip according to claim 1, wherein:
said wire extends in a direction perpendicular to a thickness direction of said semiconductor substrate.

9. The semiconductor chip according to claim 2, wherein:
said wire extends in a direction perpendicular to a thickness direction of said semiconductor substrate.

10. The semiconductor chip according to claim 7, wherein:
said wire extends in a direction perpendicular to a thickness direction of said semiconductor substrate.

11. The semiconductor chip according to claim 1, wherein:
said wire extends in a thickness direction of said semiconductor substrate.

12. The semiconductor chip according to claim 2, wherein:
said wire extends in a thickness direction of said semiconductor substrate.

13. The semiconductor chip according to claim 7, wherein:
said wire extends in a thickness direction of said semiconductor substrate.

14. The semiconductor chip according to claim 11, wherein:
said wire is a through wire which extends from a top surface to a bottom surface of said semiconductor substrate.

15. The semiconductor chip according to claim 12, wherein:
said wire is a through wire which extends from a top surface to a bottom surface of said semiconductor substrate.

16. The semiconductor chip according to claim 13, wherein:
said wire is a through wire which extends from a top surface to a bottom surface of said semiconductor substrate.

17. The semiconductor chip according to claim 1, further comprising a buried layer for electrically isolating a circuit formed on said semiconductor substrate from said semiconductor substrate.

18. A semiconductor device comprising a plurality of the semiconductor chips according to claim 1 stacked therein.

19. A semiconductor device comprising a plurality of the semiconductor chips according to claim 2 stacked therein.

20. A semiconductor device comprising a plurality of the semiconductor chips according to claim 7 stacked therein.
